(19) United States
(12) Patent Application Publication
(10) Pub. No.: US 2025/0089170 A1
(43) Pub. Date: Mar. 13, 2025

(54) STORAGE DEVICE

(71) Applicant: Samsung Electronics Co., Ltd., Suwon-si (KR)

(72) Inventors: Suin KIM, Suwon-si (KR); Minsung KIL, Suwon-si (KR)

(73) Assignee: Samsung Electronics Co., Ltd., Suwon-si (KR)

(21) Appl. No.: 18/583,215

(22) Filed: Feb. 21, 2024

(30) Foreign Application Priority Data
Sep. 8, 2023 (KR) 10-2023-0119925

(51) Int. Cl. H05K 1/14; H05K 1/02; H05K 1/18; H05K 5/00; H05K 7/20

(52) U.S. Cl. CPC H05K 1/144; H05K 1/0215; H05K 1/148; H05K 5/006; H05K 7/20445; H05K 1/18; H05K 1/182; H05K 2201/09027; H05K 2201/10015; H05K 2201/10159; H05K 2201/10522; H05K 2201/10545; H05K 2201/2018

(57) ABSTRACT

A storage device includes a first module including a first substrate and at least one first semiconductor chip provided on the first substrate, a second module electrically connected to the first module and including a second substrate and at least one second semiconductor chip provided on the second substrate, a capacitor module provided between the first module and the second module, including at least one capacitor, and electrically connected to at least one of the first and second modules, and a case configured to accommodate the first module, the second module, and the capacitor module therein.

### CROSS-REFERENCE TO RELATED APPLICATION(S)

This U.S. non-provisional application claims priority under 35 USC § 119 to Korean Patent Application No. 10-2023-0119925, filed on Sep. 8, 2023, in the Korean Intellectual Property Office, the disclosure of which is herein incorporated by reference in its entirety.

### BACKGROUND

Example embodiments relate to storage devices, and more particularly, to solid state drive (SSD) devices.

Solid state drive (SSD) devices are attracting attention as the next generation storage device to replace hard disk drives (HDDs). SSD devices are storage devices based on nonvolatile memory, and have low power consumption and high storage density. When SSD devices used as storage devices, they are capable of reading and writing large amounts of data at high speed, resulting in increased demand for SSD devices. However, SSD devices include various elements including a plurality of semiconductor chips, and it has been difficult to spatially arrange the semiconductor chips and elements. Such a spatial arrangement issue has affected the reliability of storage devices.

### SUMMARY

Some example embodiments provide solid-state drive (SSD) devices having improved product reliability.

According to an example embodiment, a storage device includes a first module including a first substrate and at least one first semiconductor chip on the first substrate, a second module electrically connected to the first module, the second module including a second substrate and at least one second semiconductor chip on the second substrate, a capacitor module between the first module and the second module, the capacitor module including at least one capacitor, and the capacitor module electrically connected to at least one of the first and second modules, and a case configured to accommodate the first module, the second module, and the capacitor module therein. At least a portion of the capacitor module is in physical contact with the case.

According to an example embodiment, a storage device includes a first module, a capacitor module, and a second module sequentially stacked and electrically connected to each other. The first module includes a first substrate and at least one first semiconductor chip on the first substrate, the capacitor module includes a capacitor substrate and at least one capacitor on the capacitor substrate, and the second module includes a second substrate and at least one second semiconductor chip on the second substrate.

According to an example embodiment, a storage device includes a capacitor module mounted in a storage device includes a first capacitor substrate and a second capacitor substrate having different thermal conductivities, at least one capacitor provided on the first and second capacitor substrates, and a frame along at least one periphery of the first and second capacitors.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a perspective view of a storage device according to an example embodiment.

FIG. 2 is an exploded perspective view of the storage device of FIG. 1.

FIG. 3 is a cross-sectional view of the storage device, taken along line A-A′ of FIG. 1.

FIG. 4 is a cross-sectional view of the storage device, taken along line B-B′ of FIG. 1.

FIG. 5A is an exploded perspective view of a portion of a storage device according to an example embodiment, illustrating a first module, a second module, and a capacitor substrate, and FIG. 5B is a cross-sectional view taken along line B-B′ of FIG. 1.

FIG. 6A is an exploded perspective view of a portion of a storage device according to an example embodiment, illustrating a first module, a second module, and a capacitor substrate, and FIG. 6B is a cross-sectional view taken along line A-A′ of FIG. 1.

FIG. 7A is an exploded perspective view of a portion of a storage device according to an example embodiment, illustrating a first module, a second module, and a capacitor substrate, and FIG. 7B is a cross-sectional view taken along line A-A′ of FIG. 1.

FIG. 8A is an exploded perspective view showing a portion of a storage device according to an example embodiment, illustrating a capacitor substrate, and FIG. 8B is a cross-sectional view taken along line B-B′ of FIG. 1.

FIG. 9A is an exploded perspective view of a portion of a storage device according to an example embodiment, illustrating a capacitor substrate, FIG. 9B is a perspective view of an assembled capacitor substrate illustrated in FIG. 9A, and FIG. 9C is a cross-sectional view taken along line B-B′ of FIG. 1.

FIG. 10A is a perspective view of a portion of a storage device according to an example embodiment, illustrating a capacitor substrate, and FIG. 10B is a cross-sectional view taken along line B-B′ of FIG. 1.

### DETAILED DESCRIPTION

The present disclosure may be modified in various ways, and may have various example embodiments, among which specific example embodiments will be described in detail with reference to the accompanying drawings. However, it should be understood that the description of the specific example embodiments of the present disclosure is not intended to limit the present disclosure to a particular mode of practice, and that the present disclosure is to cover all modifications, equivalents, and substitutes included in the spirit and technical scope of the present disclosure.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments will be described in detail with reference to the attached drawings. Like reference numerals in the drawings denote like elements, and redundant descriptions thereof will be omitted.

Some example embodiments relate to storage devices, among semiconductor devices, and more particularly, to a solid state drive (SSD) devices. A storage device may be provided in the form of a package including a printed circuit board (PCB) and a memory module with a first substrate on which semiconductor chips are mounted.

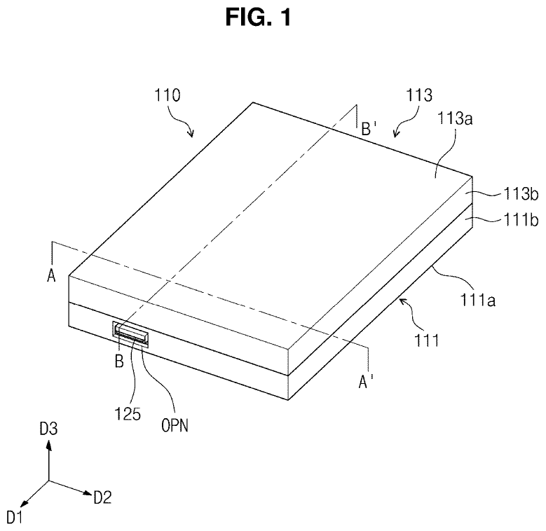

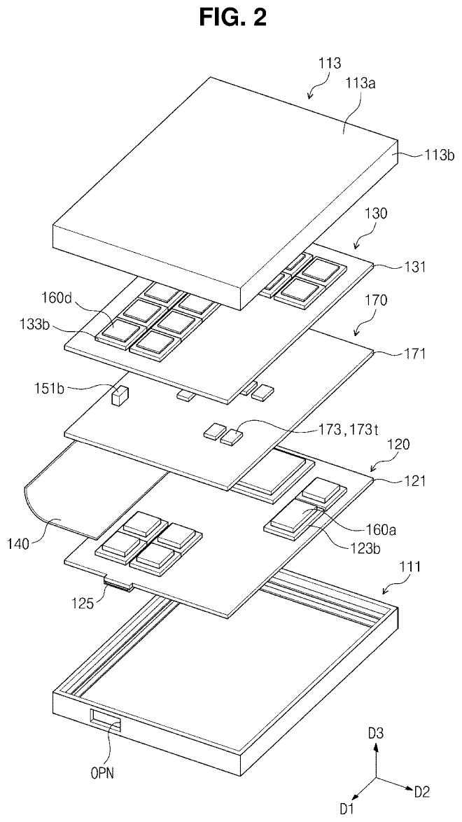

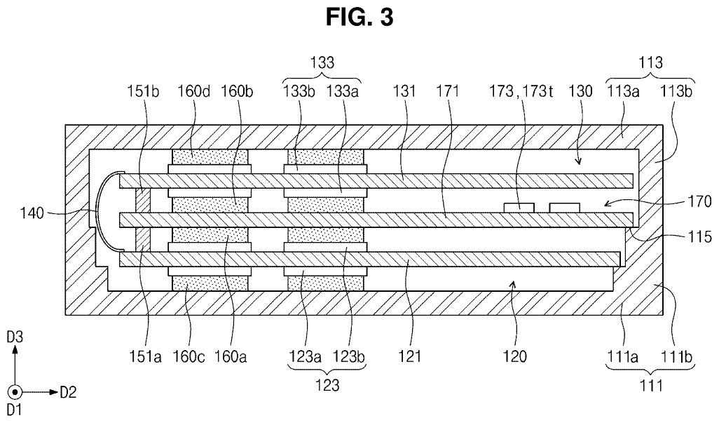

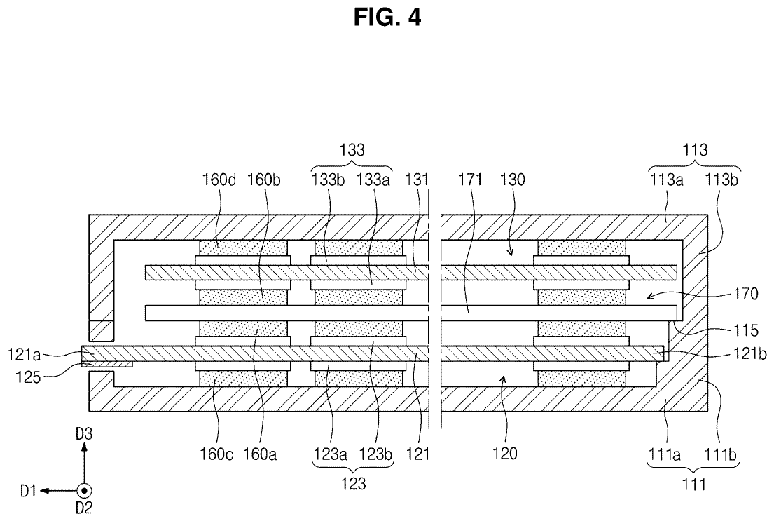

FIG. 1 is a perspective view of a storage device according to an example embodiment. FIG. 2 is an exploded perspective view of the storage device of FIG. 1. FIG. 3 is a cross-sectional view of the storage device, taken along line A-A′ of FIG. 1. FIG. 4 is a cross-sectional view of the storage device, taken along line B-B′ of FIG. 1.

Referring to FIGS. 1, 2, 3, and 4, a storage device according to an example embodiment may include a first module 120, a second module 130, and a capacitor module 170, and a case 110. The capacitor module 170 may be provided between the first module 120 and the second module 130. The case 110 may accommodate the first module 120, the second module 130, and the capacitor module 170 therein.

The case 110 may form the exterior of the storage device. The case 110 may have a three-dimensional shape having an accommodation space in which various components are accommodated, and the first module 120, the second module 130, and the capacitor module 170 may be accommodated in the accommodation space.

The case 110 may include a first case 111 and a second case 113, removably coupled to each other and sequentially disposed in a vertical direction. Hereinafter, two directions parallel to the ground and perpendicular to each other will be referred to as a first direction D1 and a second direction D2, and a direction perpendicular to the ground will be referred to as a third direction D3. For ease of description, a direction away from the ground will be referred to as an upward direction, and a direction closer to the ground will be referred to as a downward direction.

The case 110 may include first and second cases 111 and 113, sequentially disposed in the third direction D3. The first case 111 may correspond to a lower case, and the second case 113 may correspond to an upper case. The first case 111 may be coupled to the second case 113 to form an accommodation space therein.

The first case 111 may include a first plate 111a having a flat plate shape and first sidewalls 111b bent upwardly to extend from the first plate 111a. The first case 111 may include an external surface exposed to the outside and an internal surface directed toward the accommodation space. The first plate 111a and the first sidewalls 111b of the first case 111 may be individually manufactured and then assembled together. However, example embodiments are not limited thereto, and the first plate 111a and the first sidewalls 111b of the first case 111 may be formed to be integrated with each other (e.g., may be a single integral body).

An opening OPN, exposing a first external connector 125 to the outside, may be provided in one of the sidewalls of the case 110, for example, at least one sidewall among sidewalls 111b of the first case 111.

The second case 113 may include a second plate 113a having a flat plate shape and second sidewalls 113b bent downwardly to extend from the second plate 113a. The second case 113 may include an external surface exposed to the outside and an internal surface directed toward the accommodation space. The second plate 113a and the second sidewalls 113b of the second case 113 may also be individually manufactured and then assembled together. However, example embodiments are not limited thereto, and the second plate 113a and the second sidewalls 113b of the second case 113 may be formed to be integrated with each other (e.g., may be a single integral body).

In an example embodiment, the case 110 may have a hexahedral shape, but the shape of the case 110 is not limited thereto. For example, the case 110 may have a shape of polygonal column such as pentagonal column or hexagonal column, or may have a cylindrical shape.

The case 110 may include a material having high thermal conductivity to facilitate emission (e.g., dissipation) of heat, generated by components such as the first semiconductor chip 123 and/or the second semiconductor chip 133 disposed within the case 110, to the outside of the case 110. For example, the thermal conductivity of case 110 may be at least 10 W/mK or more. In addition, the case 110 may shield components disposed within the case 110 from external electromagnetic waves.

The case 110 may be formed of a single material or a combination of different materials. The case 110 may include metal, a carbon-based material, a polymer, or combinations thereof. The case 110 may include, for example, copper (Cu), aluminum (Al), zinc (Zn), tin (Sn), stainless steel, and/or clad metal containing the above materials. In some example embodiments, the case 110 may include graphite, graphene, carbon fiber, or carbon nanotube composite. In some other example embodiments, the case 110 may include epoxy resin, polymethylmethacrylate (PMMA), polycarbonate (PC), polyethylene (PE), or polypropylene (PP).

The first module 120, the second module 130, and the capacitor module 170 provided in the case 110 may be electronic components constituting storage device, and the electronic components may include an SSD controller, nonvolatile memory devices, volatile memory devices, and buffer memory devices. The SSD controller, the nonvolatile memory devices, the buffer memory devices, or the like, may be provided in the form of semiconductor chips.

The first module 120 may include a first substrate 121 and at least one first semiconductor chip 123 mounted on the first substrate 121.

The first substrate 121 is a single-layer or multilayer circuit board having upper and lower surfaces opposing each other, and may be a printed circuit board (PCB). For example, the first substrate 121 may be a double-sided PCB or a multilayer PCB. For example, the first substrate 121 may include a base layer and wiring layers formed on an upper surface and a lower surface of the base layer. A PCB may include interconnections, formed on or inside the PCB, and vias for connecting the interconnections. The interconnections may be printed circuit patterns for interconnecting the electronic components. The base layer may include at least one material selected from phenol resin, epoxy resin, and polyimide. The interconnection layers may include a conductive material, such as aluminum (Al), copper (Cu), nickel (Ni), or tungsten (W). The first semiconductor chips 123 and electronic components mounted on the first substrate 121 may be electrically connected to each other through the interconnection layers of the first substrate 121.

The first substrate 121 may have a rectangular or square shape. The first substrate 121 may extend along the first direction D1 and/or the second direction D2, and may have a first side portion 121a and a second side portion 121b opposing each other in the first direction D1.

A first external connector 125 having a connection terminal for connection to an external host system, not illustrated, may be provided on the first side portion 121a of the first substrate 121.

The first external connector 125 may be coupled to an external device (e.g., a host system). The first external connector 125 may be provided at an end portion of the first substrate 121 of the first module 120 such that an external device is removable from the first external connector 125. An opening may be formed in the first case 111 to expose the first external connector 125 to the outside, and the first external connector 125 and an external host system may be connected through the opening. In this case, the first external connector 125 may be inserted into a socket of the external device to electrically connect the external device and the storage device. The storage device may transmit and receive electrical signals to and from the external device through the first external connector 1254, and receive power desired for operation from the external device. The external device may include a variety of external devices. For example, the host system may be a laptop computer, a netbook, a mobile phone, or the like. The first external connector 125 of the first substrate 121 may include a female connector. Accordingly, the storage device may be electrically connected to a host through the first external connector 125.

However, the first external connector 125 is not limited to the above-described example and may be modified into various forms. For example, the first external connector 125 may be provided in plural, or may be provided as a male connector rather than a female connector. For ease of description, in an example embodiment, a portion of the first substrate 121 is illustrated as protruding to the outside of the case 110. However, the first substrate 121 may not protrude to the outside of the case 110. In addition, for ease of description, the first external connector 125 is illustrated as being disposed on a lower side of the first side 121a of the first substrate 121, but various types of general connectors may be provided on the first side portion 121a.

The first external connector 125 may connect a storage device according to some example embodiments to an external host to exchange signals and/or receive power. The first external connector 125 may be a connector configured to be connected to an external device in an interface compliant with, for example, the parallel advanced technology attachment (PATA) standard, the serial advanced technology attachment (SATA) standard, the SCSI standard, or the PCI Express (PCIe) standard. The SATA standard covers not only SATA-1, but also all SATA-based standards, such as SATA-2, SATA-3, and e-SATA (external SATA). The PCIe standard covers not only PCIe 1.0, but also all PCIe-based standards, such as PCIe 2.0, PCIe 2.1, PCIe 3.0, and PCIe 4.0. The SCSI standard covers all SCSI-based standards, such as parallel SCSI, serial-attached SA-SCSI (SAS), and iSCSI. In some example embodiments, the first external connector 125 may be a connector configured to support an M2 interface, an mSATA interface, or a 2.5″ interface.

The first external connector 125 may be exposed to the outside through an opening OPN formed in the sidewall of the case 110. The opening OPN may be formed in one of the first sidewalls 111b of the first case 111. However, example embodiments are not limited thereto, and the opening OPN may be formed in one of the second sidewalls 113b of the second case 113.

The second side portion 121b of the first substrate 121 may be provided with a power supply terminal for supplying power to the electronic components.

The first substrate 121 may be a single-sided or double-sided substrate. At least one first semiconductor chip 123 may be mounted on an upper surface and/or opposite surfaces of the first substrate 121 depending on whether the first substrate 121 is a single-sided substrate or a double-sided substrate. The first semiconductor chip 123 may include at least one first upper semiconductor chip 123b, mounted on the upper surface of the first substrate 121, and/or at least one first lower semiconductor chip 123a mounted on the lower surface of the first substrate 121. In this case, the first upper semiconductor chip 123b and/or the first lower semiconductor chip 123a may be provided in singular or plural. In an example embodiment, both the first upper semiconductor chip 123b and the first lower semiconductor chip 123a have been described as being mounted.

The second module 130 may include a second substrate 131 and at least one second semiconductor chip 133 mounted on the second substrate 131.

The second substrate 131 may also be a printed circuit board (PCB) as a single-layer or multilayer circuit board having upper and lower surfaces opposing each other. For example, the second substrate 131 may be a double-sided PCB or a multilayer PCB. For example, the second substrate 131 may include a base layer and interconnection layers formed on an upper surface and a lower surface of the base layer. The PCB may include interconnections, formed on or inside the PCB, and vias for connecting the interconnections. The interconnection may be printed circuit patterns for interconnecting the electronic components. The base layer may include at least one material selected from phenol resin, epoxy resin, or polyimide. The interconnection layers may include a conductive material, such as aluminum (Al), copper (Cu), nickel (Ni), or tungsten (W). The second semiconductor chips 133 and electronic components mounted on the second substrate 131 may be electrically connected to each other through the interconnection layers of the second substrate 131.

The second substrate 131 may have a rectangular or square shape. The second substrate 131 may extend in the first direction D1 and/or the second direction D2.

The second substrate 131 may be a single-sided or double-sided substrate. At least one second semiconductor chip 133 may be mounted on an upper surface and/or opposite surfaces of the second substrate 131 depending on whether the second substrate 131 is a single-sided substrate or a double-sided substrate. The second semiconductor chip 133 includes at least one second upper semiconductor chip 133b, mounted on the upper surface of the second substrate 131, and/or at least one second lower semiconductor chip 133a mounted on the lower surface of the second substrate 131. The second upper semiconductor chip 133b and/or the second lower semiconductor chip 133a may be provided in singular or plural. In an example embodiment, both the second upper semiconductor chip 133b and the second lower semiconductor chip 133a have been described as being mounted.

When a plurality of first semiconductor chips 123 are provided on the first substrate 121 and a plurality of second semiconductor chips 133 are provided on the second substrate 131, the first semiconductor chips 123 and/or the second semiconductor chips 133 may be the same type of semiconductor chip or may be different types of semiconductor chips.

In an example embodiment, the first semiconductor chip 123 and/or the second semiconductor chip 133 may include a controller chip and at least one memory semiconductor chip (e.g., a plurality of memory chips). The controller chip, the at least one semiconductor chip, or the like, may be mounted on the upper surface and/or the lower surface of the first substrate 121 and/or the second substrate 131 via connection members such as solder balls.

An SSD controller may be implemented in the controller chip. The SSD controller may exchange signals with a host through a host interface. The host interface may include a universal serial bus (USB), a small computer system interface (SCSI), a PCI express, ATA, Parallel ATA (PATA), Serial ATA (SATA), and/or Serial Attached SCSI (SAS). The signals exchanged between the SSD controller and the host may include commands, addresses, data, or the like. The SSD controller may analyze and process signals received from the host.

A portion of the controller chips may control memory semiconductor chips. A control circuit unit may be embedded in a controller chip. The control circuit unit of the controller chip may control an access to data stored in the memory semiconductor chip. The control circuit unit of the controller chip may control write and read operations of a flash memory, or the like, based on control commands from an external host. The control circuit unit of the controller chip may include an additional control semiconductor chip such as an application specific integrated circuit (ASIC). The control circuit unit of the controller chip may be configured to be automatically executed by an operating system of an external host, for example, when the storage device is connected to the external host. The control circuit unit of the controller chip may provide standard protocols such as parallel advanced technology attachment (PATA), serial advanced technology attachment (SATA), SCSI standard, or PCI Express (PCIe). In addition, the control circuit unit of the controller chip may perform wear leveling, garbage collection, bad block management, and/or error correction code for driving non-volatile memory devices. In this case, the control circuit unit of the controller chip may include a script for automatic execution and an application program that may be executed in the external host.

A portion of the memory semiconductor chips may be nonvolatile memory devices. The nonvolatile memory devices may be used as storage media for SSD. The nonvolatile memory devices may include, for example, a flash memory, a phase-change RAM (PRAM), a resistive RAM (RRAM), a ferroelectric RAM (FeRAM), and a magnetic RAM (MRAM), or the like, but example embodiments are not limited thereto. The flash memory may be, for example, a NAND flash memory. The flash memory may be, for example, a V-NAND flash memory. The nonvolatile memory device may include a single semiconductor die or may be a stack of a plurality of semiconductor dies.

Another portion of the memory semiconductor chips may be volatile memory devices. The volatile memory device may be, for example, a dynamic random access memory (DRAM), a static RAM (SRAM), or the like, but example embodiments are not limited thereto. The volatile memory device may provide a cache function of storing data frequently used when the external host accesses the storage device, and may scale access-time and data-transfer performance to match performance of the external host connected to the storage device.

A buffer memory device may be used as a buffer region to temporarily store data received from the host or to temporarily store data read from nonvolatile memory devices. In addition, the buffer memory device may be used to drive software (S/W) used to efficiently manage nonvolatile memory devices. In addition, the buffer memory device may be used to store metadata input from the host or to store cache data. For example, the buffer memory device may include at least one DRAM package. The DRAM package may include a package substrate and at least one DRAM chip mounted on the package substrate. An SSD may replace a DRAM with a volatile memory such as an SRAM, or nonvolatile memory such as flash memory, a PRAM, an MRAM, an ReRAM, and an FRAM.

In an example embodiment, although not illustrated in detail in the drawings, a resistor, capacitor, inductance, a switch, a temperature sensor, a DC-DC converter, an active devices and/or passive elements may be further mounted on the first substrate 121 and/or the second substrate 131.

A flexible connection substrate 140 may be provided between the first module 120 and the second module 130 to connect the first module 120 and the second module 130 to each other. For example, the flexible connection substrate 140 may be a flexible printed circuit board, and may have one end connected to the first substrate 121 of the first module 120 and the other end connected to the second substrate 130 of the second module 131 to electrically connect the first module 120 and the second module 130 to each other. The flexible connection substrate 140 may be bent to surround one side portion of the capacitor module 170 between one edge of the first substrate 121 and one edge of the second substrate 131. In FIG. 2, one end of the flexible connection substrate 140 is illustrated as being connected only to the first substrate 121 of the first module 120, but this is only for ease of description. As illustrated in FIG. 3, the flexible connection substrate 140 may be connected to the first substrate 121 of the first module 120. The other end of the flexible connection substrate 140 may be connected to the second substrate 131 of the second module 130.

In an example embodiment, the flexible connection substrate 140 has been described as being connected to only one side portion of the first module 120 and the second module 130, but example embodiments are not limited thereto and a plurality of flexible connection substrates 140 may be provided and locations thereof may also be changed in various ways.

The capacitor module 170 may be provided between the first module 120 and the second module 130. The capacitor module 170 may include a capacitor substrate 171 and at least one capacitor 173 mounted on the capacitor substrate 171.

Similar to the above-described first and second substrates 121 and 131, the capacitor substrate 171 may be a single-layer or multilayer circuit board having upper and lower surfaces opposing each other, and may be a printed circuit board (PCB). For example, the capacitor substrate 171 may include a base layer and interconnection layers formed on upper and lower surfaces of the base layer. The PCB may include interconnections, formed on or inside the PCB, and vias for connecting the interconnections. The interconnections may be printed circuit patterns for interconnecting the electronic components.

One or more capacitors 173 may be mounted on the capacitor substrate 171. The capacitor 173 according to the present example embodiment may include various types of capacitor such as a tantalum capacitor, an electrolytic capacitor, a film capacitor, or a ceramic capacitor, but the types are not limited thereto. For ease of description, the present example embodiment provides an example in which the capacitor 173 is a tantalum capacitor 173t.

In an example embodiment, other elements (for example, other types of active elements and passive elements), other than the capacitor 173, may be further mounted on the capacitor substrate 171. The active or passive elements may include a resistor, a capacitor, inductance, a switch, a temperature sensor, a DC-DC converter, or the like.

The capacitor module 170 and the first and second modules 120 and 130 may be electrically connected to each other. When the capacitor module 170 and the first and second modules 120 and 130 are electrically connected to each other, the capacitor module 170 and the first and second modules 120 and 130 may share a power input unit. In an example embodiment, the capacitor module 170 and the first module 120 may be electrically connected through a first contact portion 151a, and the capacitor module 170 and the second module 130 may be electrically connected to each other through a second contact portion 151b. The first contact portion 151a and the second contact portion 151b may include various types of connectors used in printed circuit boards. For example, a board connector, a high-density pin-type connector, a circular connector, a plug-in connector, a 4-pin connector, or the like, may be mainly used, but example embodiments are not limited thereto.

In an example embodiment, a single first contact portion 151a and a single second contact portion 151b are illustrated as being provided on one side of the capacitor substrate 171, but example embodiments are not limited thereto. In some example embodiments, each of the first and second contact portions 151a and 151b may be provided in plural. The locations of the first and second contact portions 151a and 151b may also be changed from the illustrated locations to other positions. In an example embodiment, the first contact portion 151a and the second contact portion 151b are illustrated as directly connecting the capacitor substrate 171 to the first substrate 121 and the second substrate 131 in the third direction D3. However, example embodiments are not limited thereto, and the capacitor substrate 171 and the first substrate 121 and the second substrate 131 may also be connected by an additional type of connector or flexible circuit board.

Similar to the first substrate 121 or the second substrate 131, the capacitor substrate 171 may extend in the second direction D2. The capacitor substrate 171 may have a rectangular or square shape. However, the shape of the capacitor substrate 171 is not limited thereto, and the capacitor substrate 170 may be provided in a different shape regardless of the shape of the first substrate 121 and/or the second substrates 131. In addition, the capacitor substrate 171 may be provided to be larger or smaller than the first substrate 121 and/or the second substrates 131. However, the size of the capacitor substrate 171 is not limited thereto, and the capacitor substrate 171 may be provided in the same size as the first substrate 121 and/or the second substrates 131.

A heat dissipation member may be provided between the capacitor module 170 and the first and second modules 120 and 130. Heat dissipation members 160a, 160b, 160c, and 160d (also referred to as 160) may include, for example, a thermal interface material (TIM). The heat dissipation member may include a first heat dissipation member 160a provided between the capacitor module 170 and the first module 120, and a second heat dissipation member 160b provided between the capacitor module 170 and the second module 130.

Each of the first and second heat dissipation members 160a and 160b may be provided between the capacitor substrate 171 and the first and second semiconductor chips 123 and 133 facing the capacitor substrate 171. For example, the first heat dissipation member 160a may be provided between a lower surface of the capacitor substrate 171 and upper surfaces of the first upper semiconductor chips 123b of the first module 120. The second heat dissipation member 160b may be provided between an upper surface of the capacitor substrate 171 and lower surfaces of the second lower semiconductor chips 133a of the second module 130. Considering that a larger amount of heat is generated from the first and second semiconductor chips 123 and 133 than from the upper surfaces of the first and second substrates 121 and 131, heat dissipation characteristics of the storage device may be effectively improved through placement of the first and second heat dissipation members 160a and 160b. However, example embodiments are not limited thereto, and the first and second heat dissipation members 160a and 160b may also be provided in direct contact between the upper surface of the first substrate 121 and the lower surface of the capacitor substrate 171, or between the lower surface of the second substrate 131 and the upper surface of the capacitor substrate 171.

According to some example embodiments, the first heat dissipation member 160a and/or the second heat dissipation member 160b may be formed of a material having high thermal conductivity but electrical insulation. The first heat dissipation member 160a and/or the second heat dissipation member 160b may include, for example, epoxy resin. Additionally, the first heat dissipation member 160a and/or the second heat dissipation member 160b may be formed of a material facilitating heat transfer, for example, a carbon material having high thermal conductivity. The carbon materials having high thermal conductivity may include graphite, graphene, and/or composites thereof, and may be prepared in a sheet-like form.

The first heat dissipation member 160a and/or the second heat dissipation member 160b may include, for example, mineral oil, grease, gap filler putty, phase change gel, phase change material pads, or particle filled epoxy. For example, commercially available greases include ShinEtsu G750, ShinEtsu G751, ShinEtsu G765, and Berquist TIC-7500; phase change materials include Thermax HF60110-BT, Chromerics T725, Chromerics T443, Chromerics T454, and Thermagon T-pcm 905c;, and a thermally conductive adhesive may include Berquist 200U, Berquist HiFlow 225-U, Berquist HiFlow 225-UT, and Chromerics therm-A-form T642, but example embodiments are not limited thereto.

The capacitor module 170 may extend substantially parallel to at least one of the second plate 113a and the first plate 111a of the case 110 within the case 110, and may also extend substantially parallel to at least one of the first and second substrates 121 and 131 of the first and second modules 120 and 130. The capacitor substrate 171 of the capacitor module 170 may extend in the first direction D1 and/or the second direction D2, so that an end portion of at least one side of the capacitor substrate 171 may be in physical contact with at least one of sidewalls of the case 110 from among the sidewalls of the first case 111. The capacitor substrate 171 is brought into direct and physical contact with at least a portion of the sidewalls of the case 110, and thus heat from the capacitor substrate 171 may be effectively dissipated to the case 110. In an example embodiment, both the capacitor module 170 and the case 110 physically connected to the capacitor module 170 may be grounded, and the capacitor substrate 171 may be brought into direct and physical contact with at least a portion of the sidewalls of the case 110 to effectively move charges accumulated in the capacitor substrate 171 to the case 110. In such a manner, accumulation of charges by components within the case 110, for example, the first semiconductor chip 123 and/or the second semiconductor chip 133 may be reduced or prevented to reduce or prevent electrostatic discharge.

The capacitor substrate 171 of the capacitor module 170 may be disposed on a staircase portion 115 of the case 110, or may be seated inside the case in the form of being inserted into a groove (not illustrated) of the case 110. For example, one end portion of the capacitor module 170 may be disposed on the staircase portion 115 of one sidewall of the first case 111, and the other end portion of the capacitor module 170 may be disposed on a sidewall, which is opposite to the one sidewall of the first case 111. The capacitor module 170 may divide an accommodation space of the case 110 into a lower accommodation space between the capacitor module 170 and the first plate 111a of the case 110 and an upper accommodation space between the capacitor module 170 and the second plate 113a of the case 110. Accordingly, the first module 120 may be disposed in the lower accommodation space, and the second module 130 may be disposed in the upper accommodation space.

In an example embodiment, the capacitor 173 may be provided in various forms. However, in some example embodiments, the capacitor 173 may be a tantalum capacitor 173t. The capacitor 173 may be provided in singular or plural, and may be provided on an upper surface or a lower surface of the capacitor substrate 171, or on both the upper and lower surfaces of the capacitor substrate 171.

In an example embodiment, at least one capacitor 173, for example, a plurality of capacitors 173, may be not provided in a region in which semiconductor chips of the first module 120 are not provided. For example, the plurality of capacitors 173 may be mounted in a region between the capacitor substrate 171 and the first module 120 where the first upper semiconductor chip 123b and the first heat dissipation member 160a are not provided. A space may be secured between the capacitor substrate 171 and the first substrate 121 because the first upper semiconductor chip 123b and the first heat dissipation member 160a are provided to be sufficiently spaced apart from each other. An additional capacitor 173 may be easily mounted in the secured space.

In addition, the plurality of capacitors 173 may be mounted in a region between the capacitor substrate 171 and the second module 130 where the second lower semiconductor chip 133a and the second heat dissipation member 160b are not provided. A space may be secured between the capacitor substrate 171 and the second substrate 131 because the second lower semiconductor chip 133a and the second heat dissipation member 160b are provided to be sufficiently spaced apart from each other. An additional capacitor 173 may be easily mounted in the secured space.

In an example embodiment, a heat dissipation member may also be provided between the first module 120 and/or second module 130 and the case 110.

The heat dissipation member may include a third heat dissipation member 160c provided between the first module 120 and the first case 111, and a fourth heat dissipation member 160d provided between the second module 130 and the second case 113.

The third and fourth heat dissipation members 160c and 160d may be provided between the first substrate 121 and the first case 111 and the second substrates 131 and the second case 113, respectively. For example, the third heat dissipation member 160c may be provided between an upper surface of the first plate 111a, among internal side surfaces of the first case 111, and a lower surface of the first lower semiconductor chips 123a of the first module 120. The fourth heat dissipation member 160d may be provided between a lower surface of the second plate 113a, among the internal side surfaces of the second case 113, and an upper surface of the second upper semiconductor chips 133b of the second module 130. At least one of the third and fourth heat dissipation members 160c and 160d may be provided as a structure providing a direct contact between the first substrate 121 and the first case 111 or between the second substrate 131 and the second case 113.

In an example embodiment, respective component may be screwed to each other. For example, screw holes may be provided in at least a portion of the components, and the components may be fastened by screws. However, a method of fastening the respective components is not limited thereto, and the respective components may be fastened using various manners such as insertion, adhesion, or the like.

The storage device having the above-described structure may significantly expand a mounting space in the first module 120 and/or the second modules 130 by modularizing the capacitor 173 and placing the modularized capacitor 173 between the first module 120 and the second module 130. According to the related arts, capacitors were also mounted on a substrate on which semiconductor chips such as memory devices were mounted. Due to the additionally mounted capacitors, a space for mounting semiconductor chips such as memory devices was not large.

However, according to an example embodiment, capacitors may be mounted on an additional capacitor substrate to expand a space in which the first semiconductor chip 123 of the first module and/or a space in which the second semiconductor chip 133 of the second module 130 are to be mounted, resulting in improved degree of freedom for mounting the first semiconductor chip 123 and/or the second semiconductor chip 133.

In addition, according to an example embodiment, the capacitor module 170 may be disposed with the first and second heat dissipation members 160a and 160b interposed between the first module 120 and the second module 130 and thus a sufficient space between the first module 120 and the capacitor module 170 and between the second module 130 and the capacitor module 170 may be secured. Accordingly, the degree of freedom for placing the capacitors 173 within the storage device may also increase. A greater number and variety of capacitors 173 may be placed on the capacitor substrate 171, and the storage device may be stably driven through such a placement of the capacitors 173.

In an example embodiment, only mounting the capacitor 173 in the space between the first module 120 and/or the second module 130 and the capacitor module 170 has been described, but example embodiments are not limited thereto. The capacitor substrate 171 may also be a circuit board, and various other types of active and passive elements may be further mounted on the capacitor substrate 171.

In addition, the capacitor module 170 may be disposed with the first and second heat dissipation members 160a and 160b interposed between the first and second modules 120 and 130 to efficiently dissipate heat, which is generated from the first and second semiconductor chips 123 and 133 mounted on the first and second modules 120 and 130, to the outside.

According to the related arts, when two modules, for example, a first module and a second module are used, a heat dissipation member is provided only on a surface of the first module and/or the second module facing a case. Therefore, there was no structure for dissipating heat between the first module and the second module. Thus, it is difficult or substantially impossible to dissipate heat from the surfaces of the first module and the second module opposing each other. In the related art, due to such a heat dissipation issue, a gap between the first module and the second module to secure a sufficient distance should be increased. The increased gap between the first module and the second module causes difficulty in making the storage device light, thin, short, and small, and/or causes a gap between the second module and an internal side surface of the second case to be reduced. In order for capacitors to be mounted, a desired (or alternatively, predetermined) gap or more should be ensured. However, when the gap between the second module and the internal side surface of the second case is reduced, the gap may not be sufficient to accommodate capacitors therein.

In contrast, in an example embodiment, the capacitor module 170 may be provided between the first module 120 and the second module 130 to substantially dissipate heat generated from the first and second semiconductor chips 123 and 133 mounted on surfaces of the first and second modules 120 and 130, along the first and second heat dissipation members 160a and 160b, the capacitor substrate 171, and the case 110. In addition, the above-described space issue may be addressed by mounting the capacitors 173 as an additional module in the storage device. Addressing the space issue has effects of reducing a heat dissipation issue, reducing a size of the case, and significantly reducing a processing area.

When an additional capacitor module 170 is adopted in a storage device as described in an example embodiment, defects may occur in elements in the capacitor module 170. Alternatively, when components for heat dissipation (e.g., the first and second heat dissipation members 160a and 160b) need to be replaced, the components may be easily replaced by replacing only the capacitor module 170 regardless of the first module 120 and/or the second module 130.

The storage device according to an example embodiment may be modified into various forms. In the following embodiments, differences from the above-described embodiment will be mainly described.

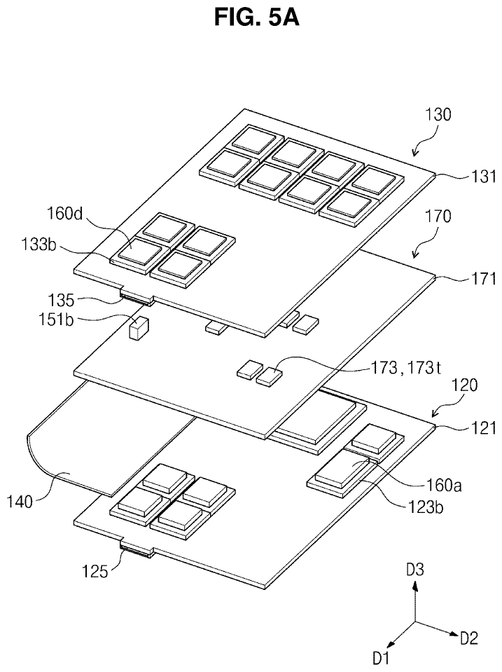

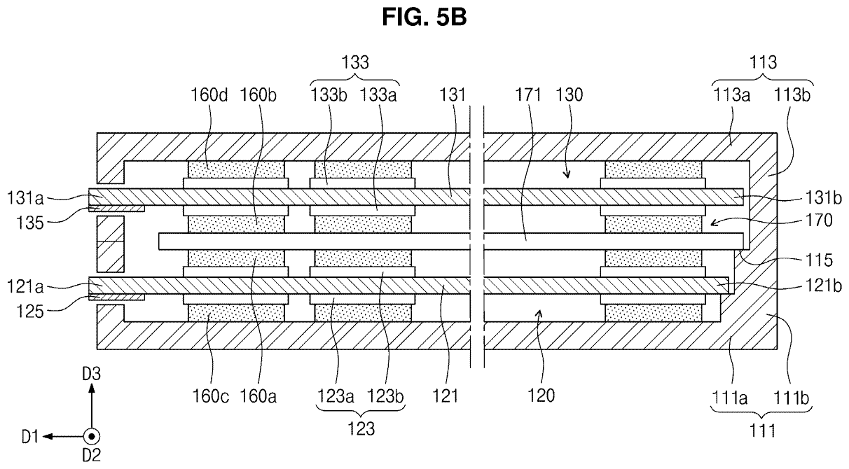

FIG. 5A is an exploded perspective view of a portion of a storage device according to an example embodiment, illustrating a first module, a second module, and a capacitor substrate, and FIG. 5B is a cross-sectional view taken along line B-B′ of FIG. 1.

Referring to FIGS. 5A and 5B, in a storage device according to an example embodiment, a second module 130 may include an external connector, for example, a second external connector 135, similarly to the case in which a first module 120 includes a first external connector 125. When the second substrate 131 has a rectangular or square shape extending in a first direction D1, the second substrate 131 may have a first side portion 131a and a second side portion 131b opposing each other in the first direction D1. The second module 130 may include a second external connector 135 on the first side portion 131a of the second substrate 131.

The second external connector 135 may be provided on the second substrate 131 on the second module 130 such that an external device (e.g., a host system) is removable therefrom, independently of the first external connector 125. An opening may be formed in a second case 113 to expose the second external connector 135 to the outside, and the second external connector 135 and an external host system may be connected to each other through the opening. In this case, the second external connector 135 may be inserted into a socket of the external device to electrically connect the external device and the storage device. Through the second external connector 135, the storage device may transmit and receive electrical signals to and from the external device, and may receive power desired for operation from the external device. A variety of external devices may be provided. For example, the host system may be a laptop computer, a netbook, a mobile phone, or the like. The second external connector 135 of the second board 131 may include a female connector. Accordingly, the storage device may be electrically connected to the host through the second external connector 135.

The second external connector 135 may be connected to an external device according to some embodiments to transmit or receive a signal and/or receive power. The first connector 125 may be a connector configured to be connected to an external device based on, for example, parallel advanced technology attachment (PATA) standards, serial advanced technology attachment (SATA) standards, small computer small interface (SCSI) standards, or PCI Express (PCIe) standards. The SATA standards include not only SATA-1 but also any SATA standards such as SATA-2, SATA-3, or external SATA (e-SATA). The PCIe standards include not only PCIe 1.0 but also any PCIe standards such as PCIe 2.0, PCIe 2.1, PCIe 3.0, or PCIe 4.0. The SCSI standards include any SCSI standards such as parallel SCSI standards, serial combination SA-SCSI (SAS) standards, or iSCSI standards. In some embodiments, the external connector may be a connector configured to support an M2 interface, an mSATA interface, or a 2.5″ interface.

In an example embodiment, the first and second external connectors 125 and 135 may be provided adjacent to each other on the same sidewall, as illustrated. In some example embodiments, the first and second external connectors 125 and 135 may be provided on different sidewalls or on at least one of the first and second plates 111a and 113a.

According to an example embodiment, the storage device may have the above-described structure, in which the first and second external connectors 125 and 135 are provided, to increase space efficiency within the storage device.

When the first and second external connectors 125 and 135 are provided adjacent to the same sidewall, a gap between the first and second external connectors 125 and 135 should be larger than or equal to a desired (or alternatively, predetermined) gap in order for the connectors to be connected to an external device. To this end, the gap between the first module 120 and the second module 130 also needs to be larger than or equal to a desired (or alternatively, predetermined) distance. Because an accommodation space in the case 110 is limited, a gap between the first and second modules 120 and 130 may be increased while a gap between the second module 130 and the second case 113 may be reduced. According to the related arts, it was difficult or substantially impossible to dissipate heat from the surfaces of the first module 120 and the second module 130 that face each other. To reduce such heat dissipation issue, second semiconductor chips 133 should be disposed between the second module 130 and the second case 113, however, it is difficult to place the second semiconductor chips 133 in a narrow gap between the second module 130 and the second case 113. In contrast, according to an example embodiment, a capacitor module 170 may be provided between the first and second modules 120 and 130. As a result, the second semiconductor chips 133 may be mounted or less mounted between the second module 130 and the second case 113. For example, in the drawing, a plurality of second semiconductor chips 133 is illustrated as being provided on both a surface of the second case 113 facing the second substrate 131 and a surface of the second substrate 131 facing the first substrate 121, for example, both an upper surface and a lower surface. However, example embodiments are not limited thereto, and the second semiconductor chips 133 may not be provided or less provided on the upper surface of the second substrate 131 that faces the second case 113 and the second semiconductor chips 133 may be provided on the lower surface of the second substrate 131 that faces the first substrate 121.

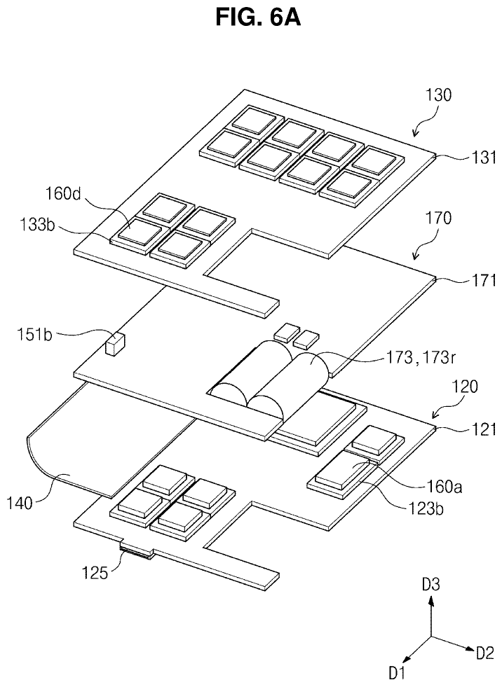

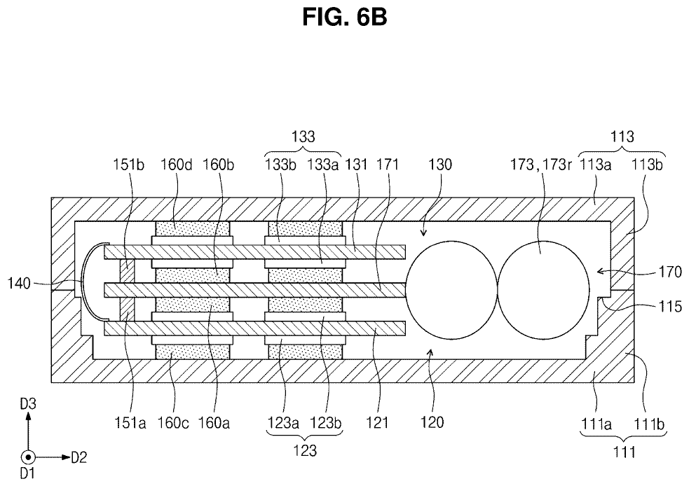

FIG. 6A is an exploded perspective view of a portion of a storage device according to an example embodiment, illustrating a first module, a second module, and a capacitor substrate, and FIG. 6B is a cross-sectional view taken along line A-A′ of FIG. 1.

Referring to FIGS. 6A and 6B, a storage device according to an example embodiment may adopt various types of capacitors, such as a radial capacitor 173r, as illustrated.

In an example embodiment, a capacitor module 170 may include a capacitor substrate 171 and at least one radial capacitor 173r connected to the capacitor substrate 171. The radial capacitor 173r may be connected to one side of the capacitor substrate 171 having a substantially quadrangular shape. When the capacitor substrate 171 is provided in a rectangular shape, the capacitor substrate 171 may have an opening provided in a region in which the radial capacitor 173r is disposed.

The radial capacitor 173r inevitably protrude upwardly and downwardly of the capacitor substrate 171 due to a radial shape thereof. Accordingly, an opening may also be provided in the first substrate 121 and/or the second substrate 131 of the first module 120 and/or the second module 130 to secure a space in which the radial capacitor 173r is to be disposed.

As described above, in an example embodiment, the capacitor substrate 171 may be separately disposed to increase the degree of freedom for placing semiconductor chips of the first module 120 and/or the second module 130. Therefore, various types of devices having various shapes may be mounted. In the present example embodiment, an example in which the capacitor 173 is a radial capacitor has been described, but other semiconductor devices, rather than the capacitor 173, or semiconductor devices having other shapes, rather than the radial shape, may be mounted on the capacitor substrate 171.

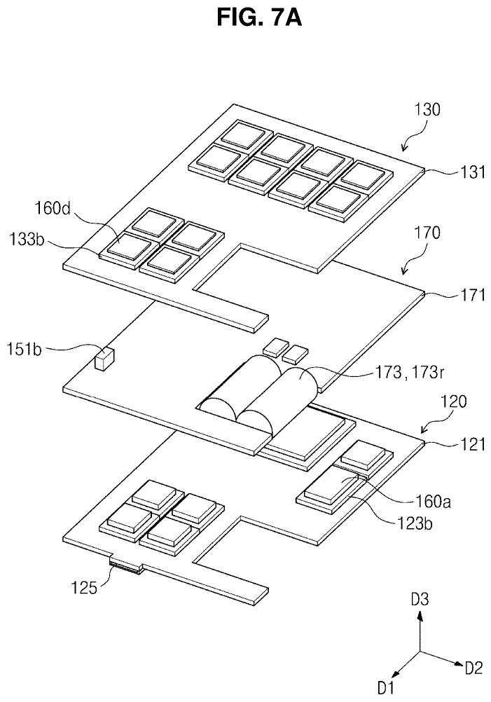

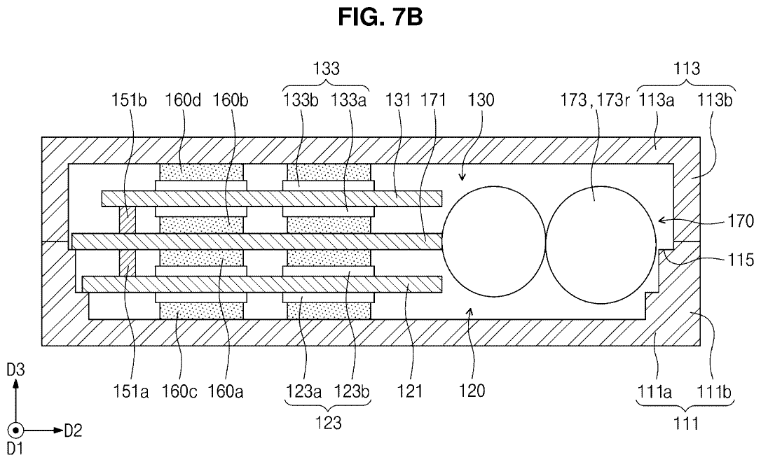

FIG. 7A is an exploded perspective view of a portion of a storage device according to an example embodiment, illustrating a first module, a second module, and a capacitor substrate, and FIG. 7B is a cross-sectional view taken along line A-A′ of FIG. 1.

Referring to FIGS. 7A and 7B, in a storage device according to an example embodiment, a flexible connection substrate 140 provided between a first module 120 and a second module 130 may be omitted. The first module 120 and the second module 130 may be connected to each other using a first contact portion 151a and a second contact portion 151b. For example, in the present example embodiment, the first and second contact portions 151a and 151b may electrically connect a capacitor module 170 and the first module 120 and may electrically connect the capacitor module 170 and the second module 130. In addition, the first and second contact portions 151a and 151b may electrically connect the first module 120 and the second module 130 via the capacitor module 170. Accordingly, signals transmitted through an additional flexible connection substrate 140 may be transmitted between the first module 120 and the second module 130 through the first contact portion 151a and the second contact portion 151b.

In the present example embodiment, each of the first contact portion 151a and the second contact portion 151b is illustrated as being provided in singular. However, example embodiments are not limited thereto and each of the first contact portion 151a and the second contact portion 151b may be provided in plural. In addition, the first contact portion 151a and the second contact portion 151b are described as being connected to only one side of the first module 120 and the second module 130, respectively. However, example embodiments are not limited thereto, and the provided locations may also be changed in various ways.

According to an example embodiment, a flexible connection substrate 140 may be omitted to reduce costs, and a process of connecting the flexible connection substrate 140 may be omitted to facilitate the manufacture of the storage device.

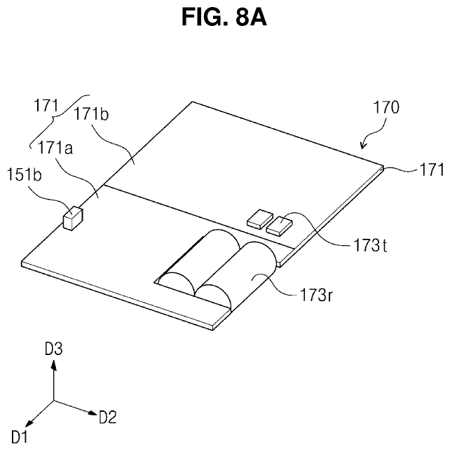

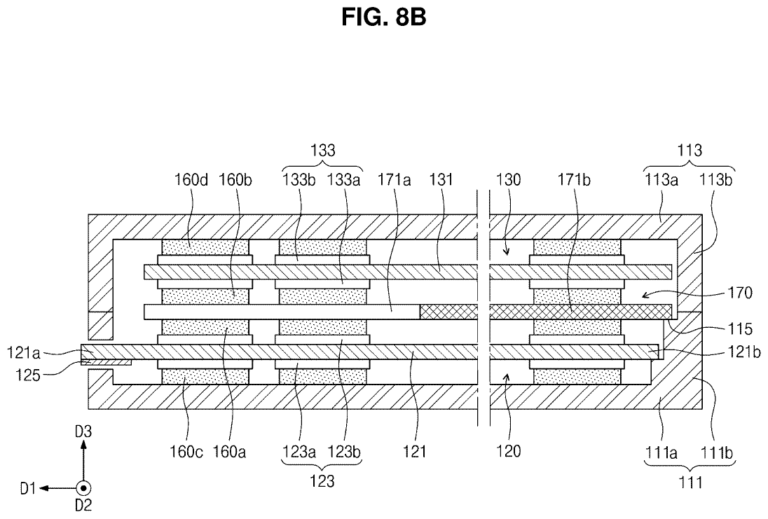

FIG. 8A is an exploded perspective view showing a portion of a storage device according to an example embodiment, illustrating a capacitor substrate, and FIG. 8B is a cross-sectional view taken along line B-B′ of FIG. 1.

Referring to FIGS. 8A and 8B, the capacitor module 170 may include two or more capacitor substrates 171 formed of different materials. For example, the capacitor module 170 may include a first capacitor substrate 171a, a second capacitor substrate 171b, and a capacitor 173 provided on the first capacitor substrate 171a and/or the second capacitor substrate 171b. Other active or passive elements, other than the capacitor 173, may be further included on the first capacitor substrate 171a and/or the second capacitor substrate 171b.

The first capacitor substrate 171a and the second capacitor substrate 171b may be formed of two or more materials having different heat conduction effects. For example, the first capacitor substrate 171a may be a printed circuit board on which interconnections are formed, and a portion excluding the interconnections may be formed of an insulating material such as glass fiber and/or polymer plastic. The second capacitor substrate 171b may be a metal substrate formed of various metals or metal alloys having high thermal conductivity. The metal substrate may be manufactured through a press process. When the second capacitor substrate 171b is a metal substrate, an insulating layer may be interposed between the interconnections and the metal substrate on at least one surface of the second capacitor substrate 171b to electrically insulate the metal substrate and the interconnections.

The first capacitor substrate 171a and the second capacitor substrate 171b may be sequentially disposed in a first direction D1 or a second direction D2, and a side surface of the first capacitor substrate 171a and a side surface of the second capacitor substrate 171b may be in direct contact with each other. An upper surface of the first capacitor substrate 171a and an upper surface of the second capacitor substrate 171b may be the same surface, but example embodiments are not limited thereto. Areas of the first capacitor substrate 171a and the second capacitor substrate 171b are not limited, and the first capacitor substrate 171a and the second capacitor substrate 171b may be modified into various shapes depending on design rules for each model.

In an example embodiment, an example in which two capacitor substrates 171 are used has been described. However, example embodiments are not limited thereto, and a larger number of capacitor substrates 171 may be used. In this case, at least one of the capacitor substrates 171 may be formed of a material having thermal conductivity, different from that of materials of the remaining capacitor substrates 171.

In the present example embodiment, at least one of the first capacitor substrate 171a or the second capacitor substrate 171b may or may not be in direct contact with the case 110.

In an example embodiment, the second capacitor substrate 171b may be provided in a region in which elements having relatively high heat generation are disposed on opposing surfaces of the first module 120 and the second module 130. For example, the second capacitor substrate 171b may be provided in a location, facing the first semiconductor chip 123 having relatively high heat generation, on the upper surface of the first substrate 121 of the first module 120. In addition, the second capacitor substrate 171b may be provided in a location, facing the second semiconductor chip 133 having relatively high heat generation, on the lower surface of the second substrate 131 of the second module 130. A first heat dissipation member and/or a second heat dissipation member may be provided between the first semiconductor chip 123 and/or the second semiconductor chip, 133 mounted on the first module 120 and/or the second module 130, and the second capacitor substrate 171b, so that heat from the first semiconductor chip 123 and/or the second semiconductor chip 133 may be effectively transferred to the second capacitor substrate 171b.

Accordingly, according to an example embodiment, heat dissipation characteristics of the storage device may be improved to drive a stable and highly reliable storage device.

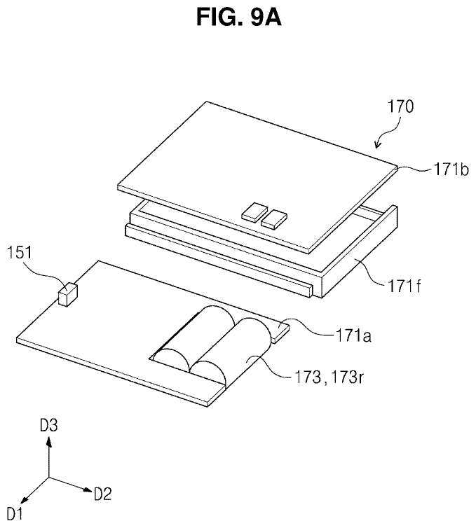

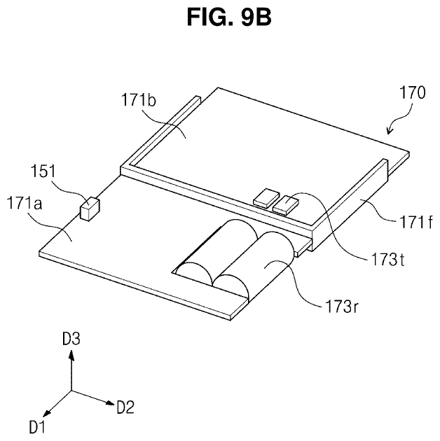

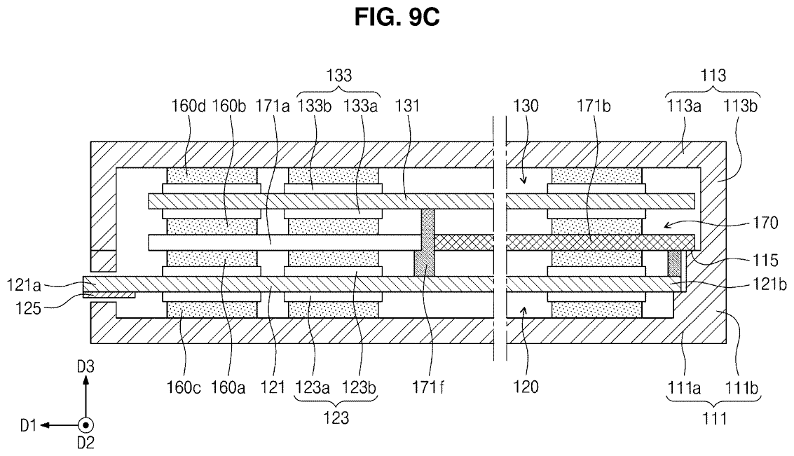

FIG. 9A is an exploded perspective view of a portion of a storage device according to an example embodiment, illustrating a capacitor substrate, FIG. 9B is a perspective view of an assembled capacitor substrate illustrated in FIG. 9A, and FIG. 9C is a cross-sectional view taken along line B-B′ of FIG. 1.

Referring to FIGS. 9A and 9B, the capacitor module 170 may further include a support frame 171f surrounding at least a portion of the capacitor substrate 171.

The capacitor module 170 may be disposed between the first substrate 121 and the second substrate 131 as described above. In an example embodiment, the support frame 171f may be a support structure for supporting the capacitor module 170 within the case 110 such that the capacitor module 170 may be fixed within the case 110.

The support frame 171f may serve as a support on which the second capacitor substrate 171b is placed when viewed in cross-section. In addition, the support frame 171f may have a sidewall provided on at least one edge and extending in a third direction D3. The sidewall of the support frame 171f may serve to support the capacitor module 170 between the first module 120 and the second module 130 and to adjust and maintain a gap between the first module 120 and the second module 130.

The support frame 171f may be formed of various materials, for example, a polymer such as plastic, but example embodiments are not limited thereto.

In addition, the support frame 171f may be provided to correspond to a portion of the capacitor substrate 171 (e.g., a portion adjacent to or corresponding to a region in which semiconductor chips having high heat generation are mounted). For example, the support frame 171f may be provided along a periphery of the second capacitor substrate 171b. The second capacitor substrate 171b may be formed of a material having high thermal conductivity, for example, metal, and may be disposed to oppose the semiconductor chips having high heat generation of the first module 120 and/or the second module and 130. Therefore, the second capacitor substrate 171b may have a relatively high temperature compared with the first capacitor substrate 171a. The support frame 171f may serve to isolate heat of the second capacitor substrate 171b such that the heat of the second capacitor substrate 171b does not affect devices in another region (e.g., semiconductor chips disposed in a region opposing the first capacitor substrate 171a). Accordingly, even when the heat generation is high, devices that are vulnerable to heat may be protected to further stabilize driving of the storage device.

According to an example embodiment, the heat dissipation effect may be further improved by providing an additional structure on the capacitor module for heat dissipation of semiconductor chips having high heat generation.

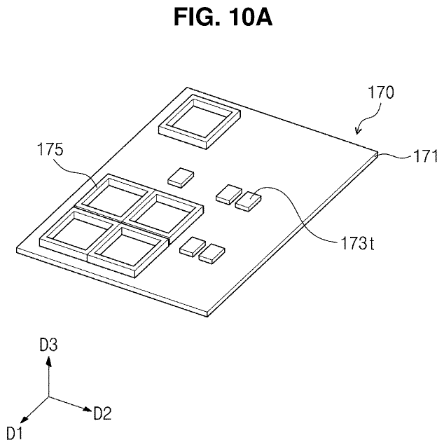

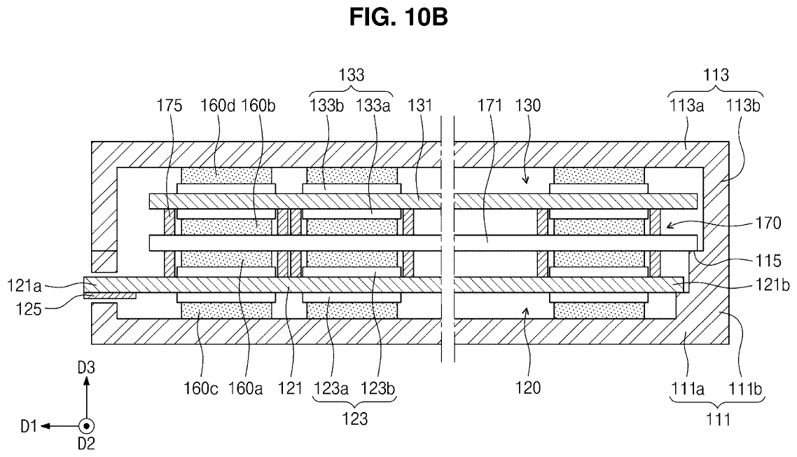

FIG. 10A is a perspective view of a portion of a storage device according to an example embodiment, illustrating a capacitor substrate, and FIG. 10B is a cross-sectional view taken along line B-B′ of FIG. 1.

Referring to FIGS. 10A and 10B, the capacitor module 170 may include a cover portion 175 provided on an upper surface and/or a lower surface of the capacitor substrate 171.

As systems including storage devices become higher-performance, various electronic devices may be used together with the storage device. Accordingly, malfunctions or failures in the storage device may be caused by electromagnetic waves that are inevitably generated in various electronic devices. Thus, it is desired to shield effects that may reduce the reliability of the storage device due to the external electromagnetic waves (e.g., electromagnetic interference (EMI)).

The cover portion 175 may be a portion for shielding the EMI, and may block electromagnetic waves emitted from the first and second semiconductor chips 123 and 133 to reduce prevent the electromagnetic waves from affecting adjacent semiconductor chips. Accordingly, even when the electromagnetic waves are emitted, devices that are vulnerable to nearby electromagnetic waves may be protected by the cover portion 175.

The cover portion 175 may be provided in a portion of the capacitor substrate 171, for example, in response to semiconductor chips from which a large amount of electromagnetic waves is emitted.

For example, the cover portion 175 may be provided on a lower surface of the capacitor substrate 171, and may be provided to oppose a semiconductor chip, from which a relatively large amount of electromagnetic waves is emitted, among the first semiconductor chips 123 provided on an upper surface of the first substrate 121. In some example embodiments, the cover portion 175 may be provided on the upper surface of the capacitor substrate 171, and may be provided to oppose a semiconductor chip, from which a relatively large amount of electromagnetic waves is emitted, among the second semiconductor chips 133 provided on a lower surface of the second substrate 131.

The cover portion 175 may protrude from the upper surface of the capacitor substrate 171 toward the second module 130 when viewed in cross-section, or may protrude from the bottom surface of the capacitor substrate 171 toward the first module 120, while surrounding at least a portion of an edge of an opposing semiconductor chip when viewed in plan view.

In an example embodiment, the cover portion 175 may have a ring shape surrounding external edges of the first and second semiconductor chips 123 and 133. However, the shape of the cover portion 175 is not limited thereto, and the cover portion 175 may be a separated ring shape with portions removed. For example, in an example embodiment, the cover portion 175 may have a quadrangular ring shape corresponding to the shape of the first and second semiconductor chips 123 and 133, for example, a square when viewed in plan view. However, the shape of the cover portion 175 is not limited thereto, and may be modified into various forms such as being provided only on at least a portion of four sides of the square, provided only on a portion corresponding to a vertex, or provided only between other chips adjacent to each other.

A storage device according to an example embodiment may be adopted in various electronic devices that require a storage medium. For example, the storage device according to an example embodiment may be used as a portable SSD replacing a hard disk drive used in a personal computer (PC), a laptop computer, or the like. In addition, the SSD may be used in mobile devices such as a smartphone, a tablet PC, a digital camera, an MP3 player, a personal digital assistant (PDA), or the like.

As set forth above, according to some example embodiments, an additional storage module may be included in a storage device to secure placement of components within the storage device and a mounting space of the components. Thus, a processing area of a case may be significantly reduced.

In addition, according to some example embodiments, an additional storage module may be included in a storage device to effectively dissipate heat generated from components with high heat generation, resulting in improved heat dissipation performance of the storage device.

While some example embodiments have been shown and described above, it will be apparent to those skilled in the art that modifications and variations could be made without departing from the scope of the present inventive concepts as defined by the appended claims.

What is claimed is:

1. A storage device comprising:
a first module comprising a first substrate and at least one first semiconductor chip on the first substrate;
a second module electrically connected to the first module, the second module comprising a second substrate and at least one second semiconductor chip on the second substrate and;
a capacitor module between the first module and the second module, the capacitor module comprising at least one capacitor, and the capacitor module electrically connected to at least one of the first and second modules; and
a case configured to accommodate the first module, the second module, and the capacitor module therein,
wherein at least a portion of the capacitor module is in physical contact with the case.

2. The storage device of claim 1, wherein
the capacitor module comprises a capacitor substrate and at least one capacitor mounted on the capacitor substrate, and an end portion of at least one side of the capacitor substrate is in physical contact with the case.

3. The storage device of claim 2, wherein
the case is grounded.

4. The storage device of claim 2, wherein
the capacitor in the capacitor module is a radial capacitor.

5. The storage device of claim 2, wherein
the capacitor in the capacitor module is a tantalum capacitor.

6. The storage device of claim 5, wherein
the capacitor is in either a first region between the capacitor substrate and the first module where the first semiconductor chip is not provided or a second region between the capacitor substrate and the second module where the second semiconductor chip is not provided.

7. The storage device of claim 1, further comprising:
a heat dissipation member at least one of between the capacitor module and the first module or between the capacitor module and the second module.

8. The storage device of claim 1, further comprising:
a first contact portion between the first substrate of the first module and the capacitor module; and
a second contact portion between the second substrate of the second module and the capacitor module,
wherein the first substrate of the first module is electrically connected to the second substrate of the second module through the first and second contact portions.

9. The storage device of claim 2, further comprising:
a cover portion on the capacitor substrate,
wherein the cover portion protrudes from the capacitor substrate toward the first module and/or the second module when viewed in cross-section, and surrounds at least a portion of the first semiconductor chip and/or the second semiconductor chip when viewed in plan view.

10. The storage device of claim 2, wherein
the capacitor substrate comprises a first capacitor substrate and a second capacitor substrate, each including a different material having different thermal conductivity.

11. The storage device of claim 10, wherein
the second capacitor substrate comprises a metal substrate.

12. The storage device of claim 10, wherein
the capacitor module is along an edge of the first capacitor substrate and/or the second capacitor substrate, and
the capacitor module further comprises a support frame configured to adjust and maintain a gap between the first module and the second module.

13. The storage device of claim 12, wherein
the support frame along a periphery of one capacitor substrate having higher thermal conductivity, from among the first capacitor substrate and the second capacitor substrate.

14. The storage device of claim 1, further comprising:
a flexible connection substrate connecting the first substrate of the first module and the second substrate of the second module.

15. The storage device of claim 1, wherein
the case comprises:
a first case opposing one surface of the first module; and
a second case opposing one surface of the second module, and
a heat dissipation member is between the first module and the first case and/or the second module and the second case.

16. The storage device of claim 1, wherein
the first module further comprises a first external connector on one side of the first substrate and connected to the first substrate, and exposed through an opening in the case.

17. The storage device of claim 16, wherein
the second module further comprises a second external connector on one side of the second substrate, connected to the second substrate, and exposed through an opening in the case.

18. A storage device comprising:
a first module, a capacitor module, and a second module sequentially stacked and electrically connected to each other, wherein
the first module comprises a first substrate and at least one first semiconductor chip on the first substrate,
the capacitor module comprises a capacitor substrate and at least one capacitor on the capacitor substrate, and
the second module comprises a second substrate and at least one second semiconductor chip on the second substrate.

19. The storage device of claim 18, further comprising:
a heat dissipation member between the first module and the at least one first semiconductor chip and between the second module and the at least one second semiconductor chip.

20. A capacitor module mounted in a storage device, the capacitor module comprising:
a first capacitor substrate and a second capacitor substrate having different thermal conductivities;
at least one capacitor provided on the first and second capacitor substrates; and
a frame along at least one periphery of the first and second capacitors.
